(19) United States
(12) Patent Application Publication
(10) Pub. No.: US 2012/0276707 A1
(43) Pub. Date: Nov. 1, 2012

(54) METHOD FOR FORMING TRENCH ISOLATION

(75) Inventors: Shing-Yih Shih, Taoyuan County (TW); Yi-Nan Chen, Taoyuan County (TW); Hsien-Wen Liu, Taoyuan County (TW)

(73) Assignee: NANYA TECHNOLOGY CORPORATION, Taoyuan (TW)

(21) Appl. No.: 13/096,985

(22) Filed: Apr. 28, 2011

(51) Int. Cl. H01L 21/31

(52) U.S. Cl. 438/400; 438/400; 257/E21.24

(57) ABSTRACT

A method for forming a trench isolation is disclosed, comprising, providing a substrate comprising a trench, forming a polysilicon layer in the trench, and subjecting the substrate to a treating process to convert the polysilicon layer to an isolating layer, wherein the treating process is fine tuned for the isolating layer on opposite sidewalls of the trench to expand to contact with each other so that the isolating layer fills the trench.

### BACKGROUND OF THE INVENTION

1. Field of the Invention

The present invention relates to methods of fabricating semiconductor integrated circuits and more particularly to a method of forming a shallow trench isolation region in a semiconductor substrate.

2. Description of the Related Art

Modern integrated circuits are made up of literally millions of individual devices such as transistors and capacitors formed in a single semiconductor substrate such as a silicon substrate. The individual devices are electrically isolated from one another through the use of various isolation techniques such as, local oxidation of silicon (LOCOS), recessed LOCOS and trench isolation.

LOCOS isolation processes are the most widely used techniques for isolating metal oxide semiconductor device (MOS) devices. A typical LOCOS isolation region is shown in FIG. 1. In a LOCOS isolation process, a silicon nitride mask 106 and pad oxide layer 104 are used to selectively grow field isolation regions 108 (i.e. field oxide regions) in a silicon substrate 102. The silicon nitride mask 106 prevents oxidation of the silicon substrate 102 where active devices are to be formed. A problem with LOCOS isolation techniques is that the oxidation step consumes substantial amounts of silicon adjacent to the isolation regions 108. This phenomenon generates what's known as a “bird's beak” 120. An advantage of the “bird's beak” 120 is that it helps reduce the leakage current (I_{off}) of adjacent transistors. A problem with creating a “bird's beak” 120, however, is that the dimensions of the isolation region 108 are increased and therefore the amount of silicon available for active devices is reduced (i.e. reduces device packing density). Another shortcoming with LOCOS isolation techniques is that approximately 45% of the isolation region 108 is grown above the silicon substrate 106 resulting in a non-planar topography which can adversely affect downstream processing steps such as photolithography. For these reasons, LOCOS processes are not well suited for the manufacturing of modern ultra large scale integrated (ULSI) circuits.

Recessed LOCOS isolation structures are similar to LOCOS isolation structures except that a groove or recess is etched into the silicon substrate prior to the oxidation step. The oxidation step then grows an oxide in the etched space and thereby forms a relatively planar isolation region. Recessed LOCOS processes, however, still suffer to some degree from non-planar topographies and lateral encroachment due to the formation of the bird's beak.

Another isolation technique which has recently received a great deal of attention is trench isolation. In a trench isolation process, a trench or groove is first etched into a silicon substrate 202 as shown in FIG. 2. Next, an oxide layer 206 is then blanket deposited over the substrate 202 and into the trench to refill the trench. The deposited oxide layer 206 is then etched back to form an isolation structure which is substantially planar with the silicon substrate 202.

Trench isolation processes are preferred over LOCOS processes because they require less substrate area than do LOCOS processes and so therefore allow for the fabrication of higher density integrated circuits. Additionally, trench isolation processes typically produce isolation structures with planar topographies which improve subsequent processing steps such as photolithography.

In order to provide good isolation properties, the trench STI typically is filled with an insulator such as a form of silicon oxide. The oxide can be deposited in a number of methods, such as a CVD, a sputtering, or a spin-on deposition process. Spin-on insulators, or spin-on dielectrics (SOD), can be deposited evenly. Additionally, SOD materials, which often form silicon oxide after being reacted, carry less risk of forming voids in the resulting insulating material than other deposition processes. The SOD precursor is reacted to form silicon oxide using a high temperature oxidation process. However, a silicon nitride liner and silicon oxide liner are required for the SOD filling process, and the SOD filling process with the two layers can not be used for isolation trenches having widths which are narrower than 15 nm. Therefore, a novel method for forming trench isolation is required.

### BRIEF SUMMARY OF INVENTION

The invention provides a method for forming a trench isolation, comprising providing a substrate comprising a trench, forming a polysilicon layer in the trench, and subjecting the substrate to a treating process to convert the polysilicon layer to an isolating layer, wherein the treating process is fine tuned for the isolating layer on opposite sidewalls of the trench to expand to contact with each other so that the isolating layer fills the trench.

A method for fabricating a semiconductor device, comprising providing a substrate comprising a trench, forming a polysilicon layer in the trench, and subjecting the substrate to a oxidation process to convert the polysilicon layer to a silicon oxide layer, wherein the treating process is fine tuned for the silicon oxide layer on opposite sidewalls of the trench to expand to contact with each other so that the silicon oxide layer fills the trench, and the silicon oxide layer outside of the trench is removed.

### BRIEF DESCRIPTION OF DRAWINGS

The invention can be more fully understood by reading the subsequent detailed description and examples with references made to the accompanying drawings, wherein,

FIG. 1 shows a typical LOCOS isolation region.

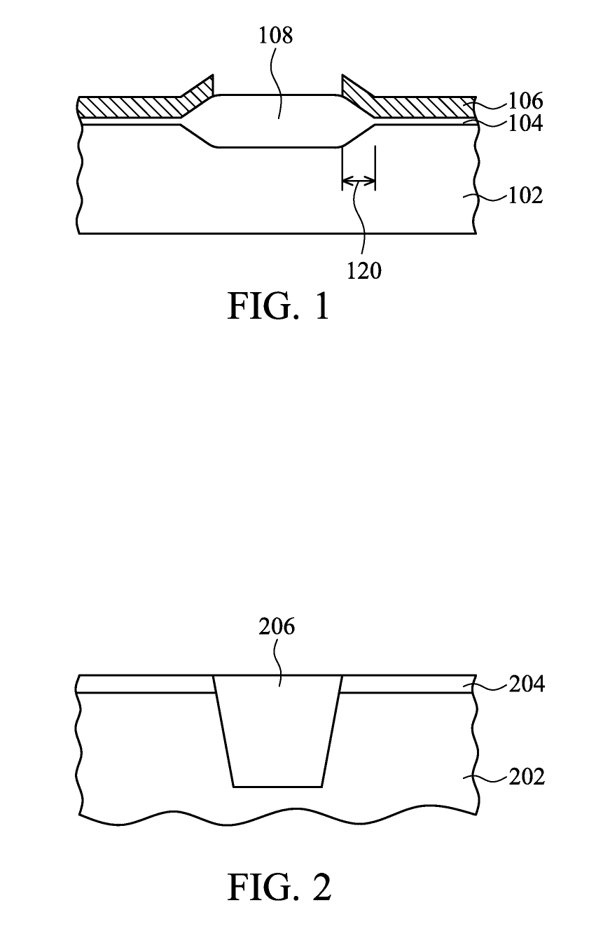

FIG. 2 shows a typical shallow trench isolation.

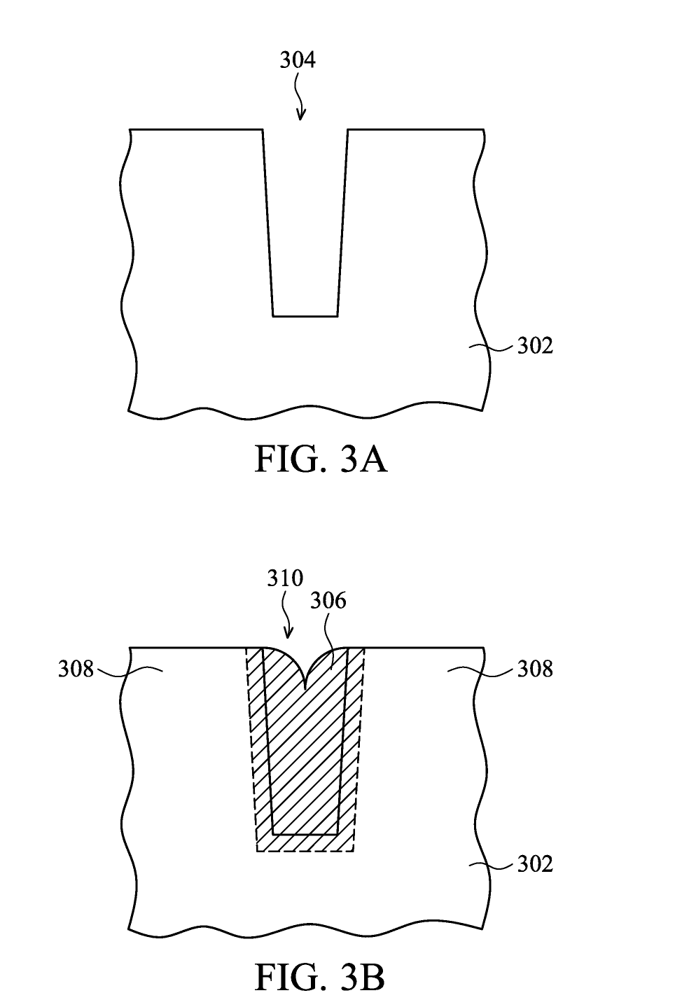

FIG. 3A to FIG. 3B illustrate a method of forming a trench isolation known by the inventor.

FIG. 4A to FIG. 4D illustrate a method of forming a trench isolation of an embodiment of the invention.

### DETAILED DESCRIPTION OF INVENTION

It is understood that specific embodiments are provided as examples to teach the broader inventive concept, and one of ordinary skill in the art can easily apply the teaching of the present disclosure to other methods or apparatus. The following discussion is only used to illustrate the invention, not limit the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

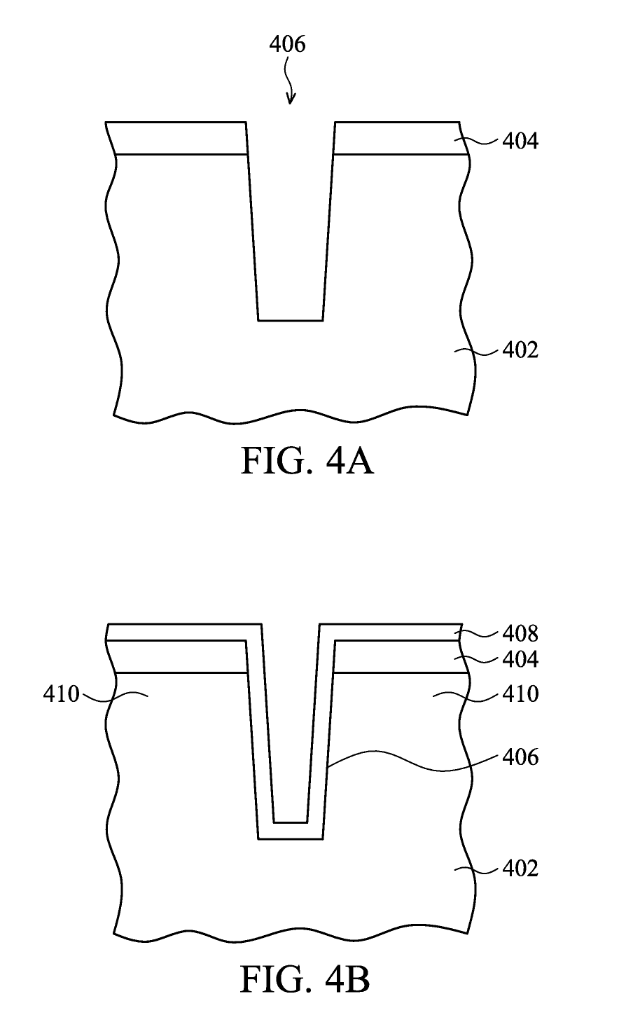

A method of forming a trench isolation known by the inventor is illustrated in accordance with FIG. 3A˜FIG. 3B. First, referring to FIG. 3A, a semiconductor substrate 302 such as silicon is provided. The substrate 302 is patterned to form a trench 304. Next, referring to FIG. 3B, the semiconductor substrate 302 is oxidized to form an oxide layer 306 in the trench 304. Specifically, the material of the semiconductor substrate 302 expands when oxidized, so that the trench 304 is filled with the oxide layer 306 to form a trench isolation 310. The method for forming a trench 304 isolation can be used for a trench 304 having a width of less than 15 nm. However, the process has a drawback as follows. The step of oxidizing the substrate 302 in the trench 304 consumes the substrate 302 material in the active areas 308. Thus, the active areas 308 in which active device can be formed thereon shrinks and the integrity of devices is affected.

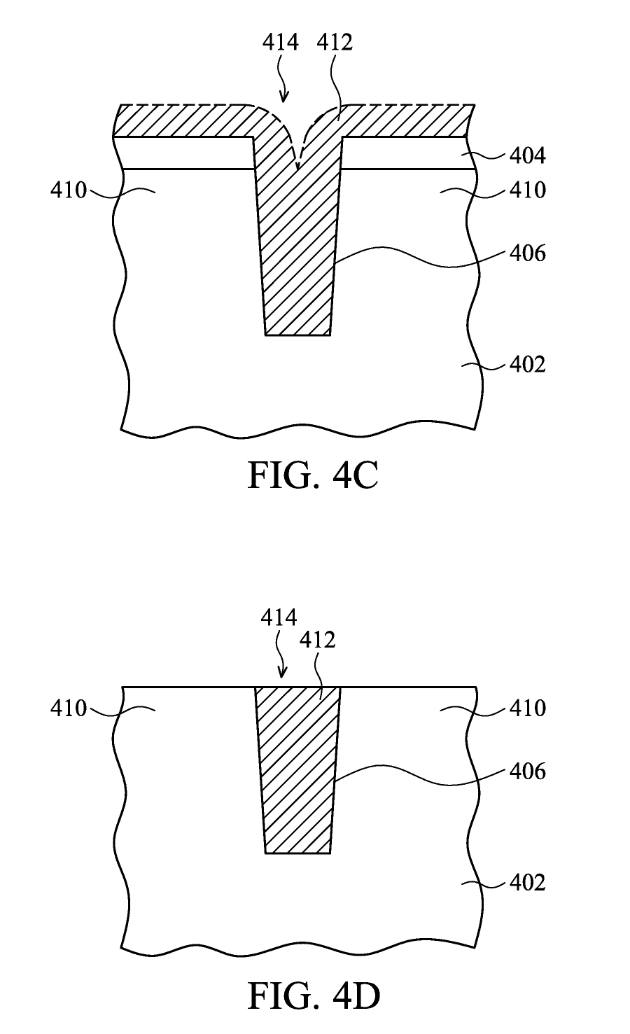

A method of forming a trench isolation of an embodiment of the invention is illustrated in accordance with FIG. 4A to FIG. 4D. Referring to FIG. 4A, a substrate 402 is provided. The substrate 402 comprises a semiconductor substrate 402 such as silicon, gallium arsenide, a rock crystal substrate, sapphire, glass, and the like. In a preferable embodiment of the invention, the substrate 402 is made of silicon. Next, a mask layer 404 is formed on the substrate 402. The mask layer 404 can be silicon nitride, silicon oxide or stack layers of silicon oxide or silicon nitride or other passivation materials. In a preferable embodiment of the invention, the mask layer 404 is made of silicon nitride. Thereafter, the mask layer 404 is patterned by lithography and etching processes and the substrate 402 is then etched to form a trench 406 using the patterned mask layer 404 as a mask. For a 30 nm node as a example, the trench 406 has a width of about 15 nm. For advanced generation technologies, the trench 406 has a width of less than 15 nm, such as 12 nm, 10 nm, 8 nm, 5 nm or below. Referring to FIG. 4B, a uniform and thick polysilicon layer 408 is formed on the mask layer 404 and on the sidewall and the bottom of the trench 406. In a preferable embodiment of the invention, the polysilicon layer 408 has a thickness in the range of about 3_-_{—}7 nm. The polysilicon layer 408 can be formed by a plasma vapor deposition (PVD), or a furnace or chemical vapor deposition (CVD) process. The low pressure chemical vapor deposition (LPCVD) method is a preferred method of forming the polysilicon layer 404 since a better conformal coating is provided by the method. Polysilicon is deposited by the pyrolysis of a silicon-bearing gas such as silane and dichlorosilane; typically, in the temperature range of about 600° C.-800° C., in an atmospheric pressure system or reduced pressure system at a low pressure of about 100-200 milli torr.

In the next process step, which is illustrated in FIG. 4C, the polysilicon layer 408 is treated to be converted into an isolating layer 412. Specifically, the polysilicon layer 408 expands when treated, so that the trench 406 is filled with the isolating layer 412 to form a trench isolation 414. It is noted that the treating process preferably is not stopped until the isolating layers 412 on opposite sidewalls of the trench 406 contact with each other for filling the trench 406. In a preferred embodiment of the invention, the polysilicon layer 408 is subjected to thermal oxidation to completely convert the polysilicon layer 408 into a polysilicon oxide filling the trench 406. A wet oxidation process such as steam oxidation at a temperature of about 900° C.-1000° C. can be employed for this conversion process. In an alternative embodiment of the invention, the polysilicon layer 408 is subjected to thermal nitridation to completely convert the polysilicon layer 408 into a polysilicon nitride filling the trench 406. For a 30 nm node which the width of the trench 406 being about 15 nm as an example, thickness of the polysilicon layer 408 preferably is 3 nm-7 nm, and the oxidation process has a process condition of process temperature of about 700° C.-1000° C., process duration of about 30 minitues-120 minitues in O₂ or Steam ambient. Further, the process condition of the treatment process and thickness of the isolating layer 412 is fine tuned so that the substrate material in the active areas 410 is not consumed by the formation of the isolating layer 412 and integrity of devices is not affected. Moreover, the process condition of the treatment process is preferably fine tuned for the isolating layer 412 to have no seam therein so that the trench isolation 414 can provide good isolating characteristics.

Next, referring to FIG. 4D, a grinding process or an etching process is performed to remove the isolating layer 412 and the mask layer 404 outside of the trench 406 to finalize the trench isolation 414. It is noted that only one trench isolation 414 is formed in the discussion above for simplicity. In reality, a plurality of trench isolations 414 are formed in the substrate 402.

The method of forming trench isolation of the invention has advantages as follows. First, the method of forming trench isolation of the invention can be applied in advanced semiconductor devices below the 30 nm node which includes trenches having widths less than 15 nm and provide good isolating characteristics. Second the method of forming the trench isolation of the invention does not consume substrate material in the active area so that device integrity is not negatively affected.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a trench isolation, comprising:
providing a substrate comprising a trench;
forming a polysilicon layer in the trench; and
subjecting the substrate to a treating process to convert the polysilicon layer to an isolating layer, wherein the treating process is fine tuned for the isolating layer on opposite sidewalls of the trench to expand to contact with each other so that the isolating layer fills the trench.

2. The method for forming a trench isolation as claimed in claim 1, wherein the treating process is an oxidation treating process.

3. The method for forming a trench isolation as claimed in claim 1, wherein the treating process is a nitridation treating process.

4. The method for forming a trench isolation as claimed in claim 1, wherein the trench has a width of less than 15 nm.

5. The method for forming a trench isolation as claimed in claim 1, wherein the isolating layer is made of silicon oxide.

6. The method for forming a trench isolation as claimed in claim 1, wherein the isolating layer is made of silicon nitride.

7. The method for forming a trench isolation as claimed in claim 1, wherein a mask layer is formed on the substrate and the step of forming the polysilicon layer further forms the polysilicon layer on the mask layer.

8. The method for forming a trench isolation as claimed in claim 7, wherein the mask layer is made of silicon nitride.

9. The method for forming a trench isolation as claimed in claim 1, wherein the process condition of the treating process is fine tuned so that the isolating layer fills the trench with substantially no seams therein.

10. The method for forming a trench isolation as claimed in claim 7, further comprising removing the mask layer and the isolating layer outside of the trench.

11. The method for forming a trench isolation as claimed in claim 1, wherein the substrate comprises active areas and the treating process is fine tuned for the substrate in the active area to not be consumed by the treating process.

12. A method for fabricating a semiconductor device, comprising:
providing a substrate comprising a trench;
forming a polysilicon layer in the trench; and
subjecting the substrate to a oxidation process to convert the polysilicon layer to a silicon oxide layer, wherein the treating process is fine tuned for the silicon oxide layer on opposite sidewalls of the trench to expand to contact with each other so that the silicon oxide layer fills the trench; and
removing the silicon oxide layer outside of the trench.

13. The method for fabricating a semiconductor device as claimed in claim 12, wherein the trench has a width of less than 15 nm.

14. The method for fabricating a semiconductor device as claimed in claim 12, wherein a mask layer is formed on the substrate and the step of forming the polysilicon layer further forms the polysilicon layer on the mask layer.

15. The method for fabricating a semiconductor device as claimed in claim 12, wherein the mask layer is made of silicon nitride.

16. The method for fabricating a semiconductor device as claimed in claim 15, further comprising removing the mask layer outside of the trench.

17. The method for fabricating a semiconductor device as claimed in claim 12, wherein process condition of the treating process is fine tuned so that the isolating layer fills the trench with substantially no seams therein.

18. The method for fabricating a semiconductor device as claimed in claim 12, wherein the substrate comprises active areas and the oxidation process is fine tuned for the substrate in the active areas to not be consumed by the oxidation process.

19. The method for fabricating a semiconductor device as claimed in claim 12, wherein the oxidation process is wet oxidation process.

20. The method for fabricating a semiconductor device as claimed in claim 12, wherein the oxidation process has a temperature of 700° C.-1000° C.
